(19) United States
(12) Patent Application Publication
(10) Pub. No.: US 2024/0413265 A1
(43) Pub. Date: Dec. 12, 2024

(54) METHOD FOR MANUFACTURING LIGHT-EMITTING DEVICE

(71) Applicant: NICHIA CORPORATION, Tokushima (JP)

(72) Inventor: Yoshiki MATSUSHITA, Tokushima-shi (JP)

(21) Appl. No.: 18/737,239

(22) Filed: Jun. 7, 2024

(30) Foreign Application Priority Data
Jun. 12, 2023 (JP) 2023-096368

(51) Int. Cl. H01L 33/00

(52) U.S. Cl. CPC H01L 33/0095; H01L 2933/0016; H01L 2933/0025; H01L 2933/0041

(57) ABSTRACT

A method for manufacturing a light-emitting device includes providing a layered body including a wavelength conversion layer, a light-transmissive layer disposed above the wavelength conversion layer, and a semiconductor layer disposed above the light-transmissive layer, separating the semiconductor layer into a plurality of semiconductor portions above the wavelength conversion layer by removing a part of the semiconductor layer; and singulating the layered body into a plurality of light-emitting devices by cleaving the wavelength conversion layer along a portion where the part of the semiconductor layer is removed.

### CROSS-REFERENCE TO RELATED APPLICATION

This application claims priority to Japanese Patent Application No. 2023-096368, filed above Jun. 12, 2023, the disclosure of which is hereby incorporated by reference in its entirety.

### TECHNICAL FIELD

The present disclosure relates to a method for manufacturing a light-emitting device.

### BACKGROUND

Japanese Patent Publication No. 2010-141176 discloses a method for manufacturing a light-emitting device that includes: a step of detaching a substrate above which a semiconductor layered body is grown, to expose a first surface of the semiconductor layered body; a step of forming a phosphor layer above the exposed first surface; and a step of performing singulation after forming the phosphor layer above the first surface.

### SUMMARY

An object of the present disclosure is to provide a method for manufacturing a light-emitting device that allows easy singulation while reducing damage to a layered body.

According to an aspect of the present disclosure, a method for manufacturing a light-emitting device includes providing a layered body including a wavelength conversion layer, a light-transmissive layer disposed above the wavelength conversion layer, and a semiconductor layer disposed above the light-transmissive layer; separating the semiconductor layer into a plurality of semiconductor portions above the wavelength conversion layer by removing a part of the semiconductor layer; and singulating the layered body into a plurality of light-emitting devices by cleaving the wavelength conversion layer along a portion where the part of the semiconductor layer is removed.

The present disclosure can provide a method for manufacturing a light-emitting device that allows easy singulation while reducing damage to a layered body.

### BRIEF DESCRIPTION OF DRAWINGS

FIG. 1A is a schematic cross-sectional view for explaining a step of a method for manufacturing a light-emitting device according to a first embodiment.

FIG. 1B is a schematic cross-sectional view for explaining a step of the method for manufacturing the light-emitting device according to the first embodiment.

FIG. 1C is a schematic cross-sectional view for explaining a step of the method for manufacturing the light-emitting device according to the first embodiment.

FIG. 1D is a schematic cross-sectional view for explaining a step of the method for manufacturing the light-emitting device according to the first embodiment.

FIG. 1E is a schematic cross-sectional view for explaining a step of the method for manufacturing the light-emitting device according to the first embodiment.

FIG. 1F is a schematic cross-sectional view for explaining a step of the method for manufacturing the light-emitting device according to the first embodiment.

FIG. 1G is a schematic cross-sectional view for explaining a step of the method for manufacturing the light-emitting device according to the first embodiment.

FIG. 1H is a schematic cross-sectional view for explaining a step of the method for manufacturing the light-emitting device according to the first embodiment.

FIG. 1I is a schematic cross-sectional view for explaining a step of the method for manufacturing the light-emitting device according to the first embodiment.

FIG. 1J is a schematic cross-sectional view for explaining a step of the method for manufacturing the light-emitting device according to the first embodiment.

FIG. 1K is a schematic cross-sectional view for explaining a step of the method for manufacturing the light-emitting device according to the first embodiment.

FIG. 1L is a schematic cross-sectional view for explaining a step of the method for manufacturing the light-emitting device according to the first embodiment.

FIG. 2A is a schematic cross-sectional view for explaining a step of a method for manufacturing a light-emitting device according to a second embodiment.

FIG. 2B is a schematic cross-sectional view for explaining a step of the method for manufacturing the light-emitting device according to the second embodiment.

FIG. 3A is a schematic cross-sectional view for explaining a step of a method for manufacturing a light-emitting device according to a third embodiment.

FIG. 3B is an enlarged cross-sectional view of a portion A in FIG. 3A.

FIG. 3C is a schematic cross-sectional view for explaining a step of the method for manufacturing the light-emitting device according to the third embodiment.

FIG. 3D is a schematic cross-sectional view for explaining a step of the method for manufacturing the light-emitting device according to the third embodiment.

### DETAILED DESCRIPTIONS

Embodiments are described below with reference to the drawings. In the drawings, the same constituent elements are denoted using the same reference signs. Note that the drawings schematically illustrate embodiments, and thus scales, intervals, positional relationships, and the like of members may be exaggerated, or some of the members are not illustrated in the drawings in some cases. As a cross-sectional view, an end view illustrating only a cut surface may be illustrated. In the cross-sectional view, the cross section of a semiconductor layer is not hatched in order to make it easy to see the boundary between layers of the semiconductor layer.

In the following description, components having substantially the same function may be denoted by the same reference signs and a description thereof may be omitted. Terms indicating a specific direction or position (for example, “upper”, “upward”, “lower”, “downward”, and other terms including or related to those terms) may be used. However, these terms are used merely to make it easy to understand relative directions or positions in the referenced drawing. As long as the relative direction or position is the same as that described in the referenced drawing using the term such as “upper” “upward”, “lower”, or “downward” in drawings other than the drawings of the present disclosure, actual products, and the like, components need not be arranged in the same manner as that in the referenced drawing. In the present specification, a positional relationship expressed by using the term “on” includes a case in which an object is in contact and also a case in which an object is not in contact but located above. In the present specification, unless otherwise specified, a case in which a member covers an object to be covered includes a case in which the member is in contact with the object to be covered and directly covers the object to be covered, and a case in which the member is not in contact with the object to be covered and indirectly covers the object to be covered. A “plan view” refers to a plan view in which a semiconductor layer above a wavelength conversion layer is viewed from above.

### First Embodiment

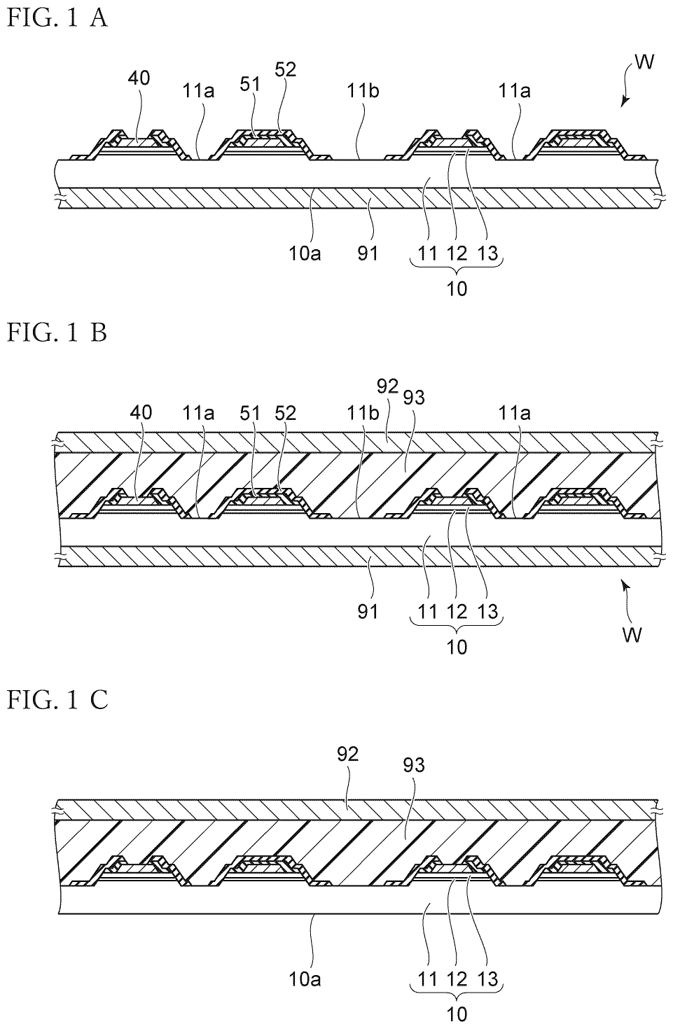

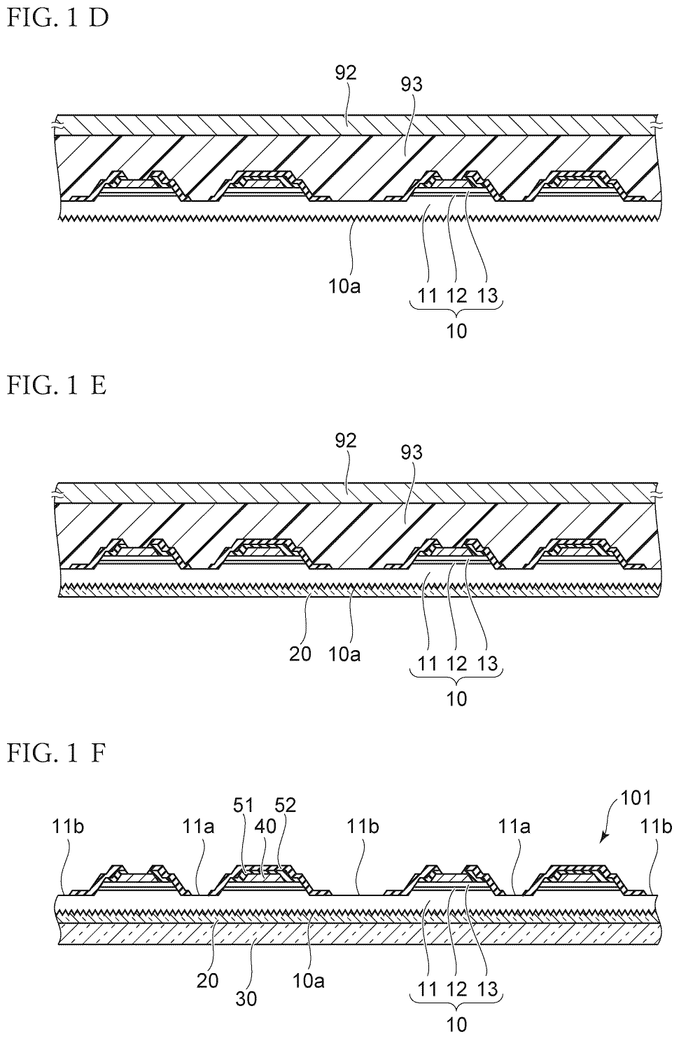

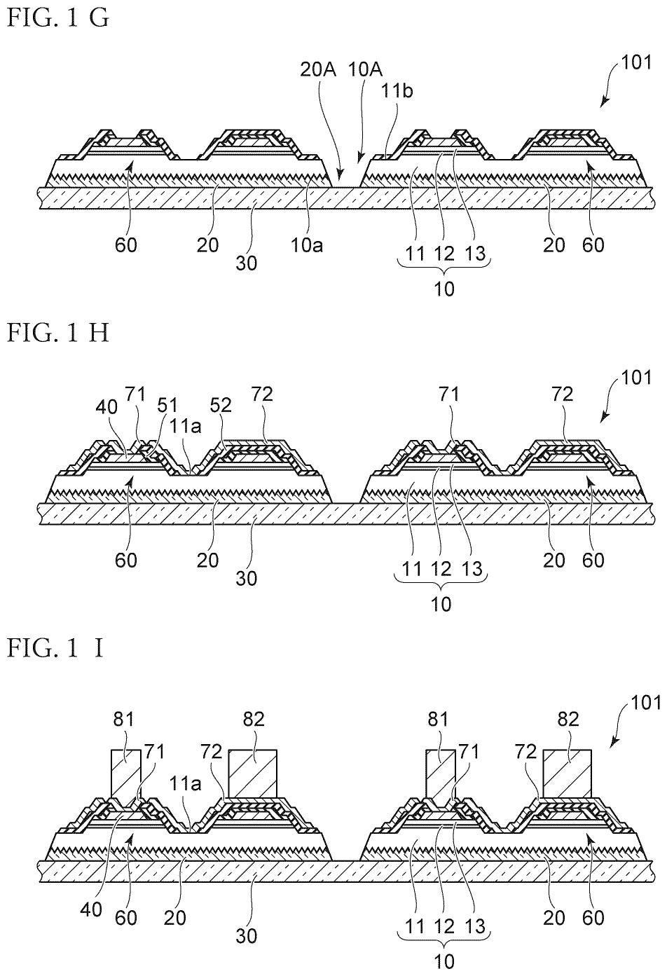

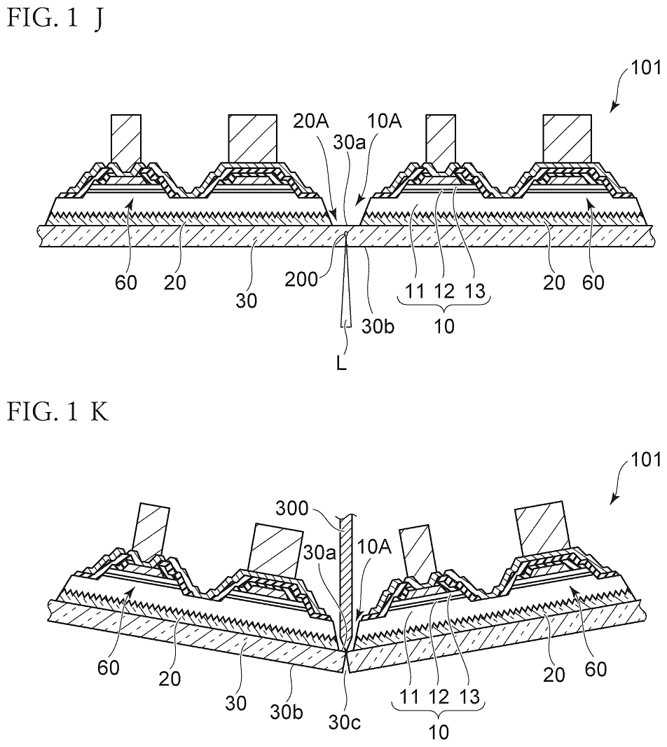

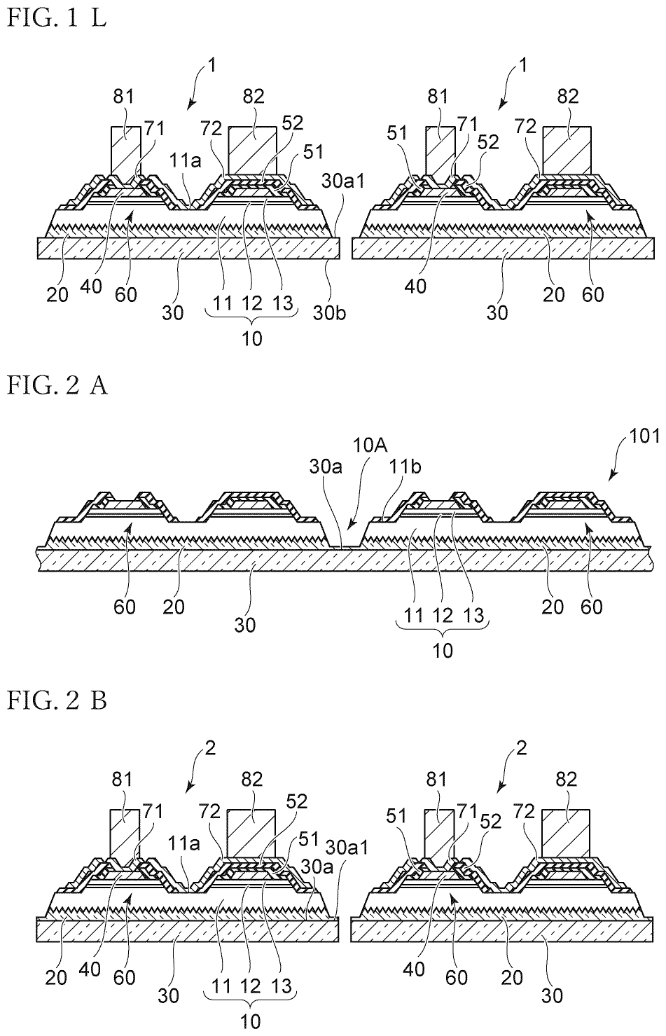

A method for manufacturing a light-emitting device 1 according to a first embodiment is described with reference to FIGS. 1A to 1L.

The method for manufacturing the light-emitting device according to the first embodiment includes a step of providing a layered body 101 including a wavelength conversion layer 30, a light-transmissive layer 20, and a semiconductor layer 10, a step of separating the semiconductor layer 10 into a plurality of semiconductor portions 60 above the wavelength conversion layer 30, and a step of singulating the layered body 101 into a plurality of light-emitting devices 1 by cleaving the wavelength conversion layer 30.

### Step of Providing Layered Body:

As illustrated in FIG. 1F, the layered body 101 includes the wavelength conversion layer 30, the light-transmissive layer 20 disposed above the wavelength conversion layer 30, and the semiconductor layer 10 disposed above the light-transmissive layer 20. The layered body 101 illustrated in FIG. 1F can be purchased to be provided. Alternatively, the step of providing the layered body 101 may include the steps described hereinafter with reference to FIGS. 1A to 1E.

### Semiconductor Layer:

The semiconductor layer 10 includes an n-side semiconductor layer 11, a p-side semiconductor layer 13, and an active layer 12 located between the n-side semiconductor layer 11 and the p-side semiconductor layer 13. The active layer 12 is a light-emitting layer that emits light, and emits light having a light emission peak wavelength in a range from 210 nm to 580 nm, for example. The active layer 12 may have, for example, a multiple quantum well (MQW) structure including a plurality of barrier layers and a plurality of well layers. The n-side semiconductor layer 11 includes a semiconductor layer containing n-type impurities. The p-side semiconductor layer 13 includes a semiconductor layer containing p-type impurities.

The semiconductor layer 10 has a first surface 10a located on an opposite side to a surface above which the active layer 12 and the p-side semiconductor layer 13 are disposed. Light emitted by the active layer 12 is mainly extracted from the first surface 10a to the outside of the semiconductor layer 10.

The n-side semiconductor layer 11 has a first n-side exposed surface 11a and a second n-side exposed surface 11b that are located on the opposite side of the first surface 10a and exposed from the active layer 12 and the p-side semiconductor layer 13.

The semiconductor layer 10 is formed of a nitride semiconductor. In the present specification, for example, it is assumed that the “nitride semiconductor” includes semiconductors having all compositions of a chemical formula of InₓAl_{y}Ga_{1-x-y}N (0≤x≤1, 0≤y≤1, x+y≤1) provided that the composition ratios x and y are changed within the respective ranges. In the above chemical formula, it is assumed that the “nitride semiconductor” includes a semiconductor further containing a group V element other than nitrogen (N), and a semiconductor further containing various elements added to control various physical properties such as a conductivity type.

### Wavelength Conversion Layer:

The wavelength conversion layer 30 converts the wavelength of at least a part of light emitted by the active layer 12. As the wavelength conversion layer 30, a sintered body that is formed by sintering powder of a phosphor and is substantially made of only the phosphor can be used. Alternatively, as the wavelength conversion layer 30, a light-transmissive material containing a phosphor can be used. Examples of the light-transmissive material that can be used include ceramics, a resin, and glass. Examples of the phosphor that can be used include a cerium-activated yttrium-aluminum-garnet-based phosphor (for example, (Y,Gd)₃(Al,Ga)₅O₁₂:Ce), and a cerium-activated lutetium-aluminum-garnet-based phosphor (for example, Lu₃(Al,Ga)₅O₁₂:Ce). A thickness of the wavelength conversion layer 30 can be, for example, in a range from 30 μm to 500 μm.

### Light-Transmissive Layer:

The light-transmissive layer 20 is located between the semiconductor layer 10 and the wavelength conversion layer 30. Because the light-transmissive layer 20 is located between the semiconductor layer 10 and the wavelength conversion layer 30, the bonding force between the semiconductor layer 10 and the wavelength conversion layer 30 can be easily increased as compared with a case in which the semiconductor layer 10 and the wavelength conversion layer 30 are directly bonded to each other.

The light-transmissive layer 20 has high light transmissivity with respect to light emitted by the active layer 12. The fact that the light-transmissive layer 20 has high light transmissivity means that the light-transmissive layer 20 has a light transmittance of 50% or more, preferably 60% or more, more preferably 80% or more with respect to the light emission peak wavelength of the light emitted by the active layer 12.

The light-transmissive layer 20 preferably has a refractive index between a refractive index of the semiconductor layer 10 and a refractive index of the wavelength conversion layer 30. Thus, the difference between the refractive index of the semiconductor layer 10 and the refractive index of the wavelength conversion layer 30 can be reduced, and reflection of light emitted by the active layer 12 between the semiconductor layer 10 and the wavelength conversion layer 30 can be reduced. For example, the refractive index of the semiconductor layer 10 can be appropriately selected in a range from 2.3 to 2.6, the refractive index of the wavelength conversion layer 30 can be appropriately selected in a range from 1.7 to 1.9, and the refractive index of the light-transmissive layer 20 can be appropriately selected in a range from 1.6 to 2.4.

Examples of a material for the light-transmissive layer 20 that can be used include SiO₂, SiN, SiON, Al₂O₃, Nb₂O₅, and TiO₂. A thickness of the light-transmissive layer 20 can be, for example, in a range from 2 μm to 50 μm.

Step of Separating Semiconductor Layer into Plurality of Semiconductor Portions:

After the layered body 101 is provided, a part of the semiconductor layer 10 is removed to separate the semiconductor layer 10 into the plurality of semiconductor portions 60 above the wavelength conversion layer 30 as illustrated in FIG. 1G. A portion 10A where the part of the semiconductor layer 10 is removed serves as a gap between adjacent semiconductor portions 60 separated from each other, and is formed in, for example, a lattice shape in plan view.

A portion below the second n-side exposed surface 11b of the n-side semiconductor layer 11 is removed, and the semiconductor layer 10 is separated into the plurality of semiconductor portions 60. In the step of separating the semiconductor layer 10 into the plurality of semiconductor portions 60, the part of the semiconductor layer 10 is preferably removed by etching. Thus, chipping of the semiconductor layer 10 is less likely to occur than in a case in which the part of the semiconductor layer 10 is removed using a blade.

For example, a portion other than a part of the second n-side exposed surface 11b in the layered body 101 is covered with a mask, and the part of the semiconductor layer 10 formed of a nitride semiconductor can be removed by a reactive ion etching (RIE) method using a chlorine-containing gas. The etching proceeds toward the first surface 10a in the thickness direction of the semiconductor layer 10 from the second n-side exposed surface 11b exposed from the mask. For example, a resist mask can be used as the mask.

In the example illustrated in FIG. 1G, in the step of separating the semiconductor layer 10 into the plurality of semiconductor portions 60, a part of the light-transmissive layer 20 is also removed, and the wavelength conversion layer 30 is exposed from the semiconductor layer 10 and the light-transmissive layer 20 in the portion 10A where the part of the semiconductor layer 10 is removed. Below the portion 10A where the part of the semiconductor layer 10 is removed, a portion 20A where the part of the light-transmissive layer 20 is removed is located. The portion 10A where the part of the semiconductor layer 10 is removed and the portion 20A where the part of the light-transmissive layer 20 is removed are gaps extending in a direction through planes above and parallel to an upper surface of the wavelength conversion layer 30. The light-transmissive layer 20 located below the semiconductor portions 60 is separated into a plurality of portions by the portion 20A where the part of the light-transmissive layer 20 is removed.

For example, when the light-transmissive layer 20 contains silicon oxide, the part of the light-transmissive layer 20 can be removed by the RIE method using a fluorine-containing gas. In the case of the RIE method, the part of the semiconductor layer 10 and the part of the light-transmissive layer 20 can be successively removed by switching the type of gas.

Step of Singulating Layered Body into Plurality of Light-Emitting Devices:

After the semiconductor layer 10 is separated into the plurality of semiconductor portions 60, the wavelength conversion layer 30 is cleaved along the portion 10A where the part of the semiconductor layer 10 is removed, thereby singulating the layered body 101 into the plurality of light-emitting devices 1 as illustrated in FIG. 1L.

For example, the wavelength conversion layer 30 can be cleaved by irradiating the wavelength conversion layer 30 with laser light and applying a pressing force to the wavelength conversion layer 30.

As illustrated in FIG. 1J, laser light L irradiates inside the wavelength conversion layer 30 from a third surface 30b of the wavelength conversion layer 30 on the opposite side to a second surface 30a on the side where the light-transmissive layer 20 and the semiconductor portion 60 are disposed. Alternatively, the laser light L may irradiate inside the wavelength conversion layer 30 from the second surface 30a. When the laser light L irradiates from the third surface 30b, the semiconductor portion 60 is less likely to be damaged by the laser light L than when the laser light L irradiates from the second surface 30a.

The laser light L is condensed at a specific depth position inside the wavelength conversion layer 30, the energy of the laser light L is concentrated at this position, and a modified portion 200 is formed inside the wavelength conversion layer 30. The modified portion 200 is a portion more embrittled than a portion where the laser light L is not condensed. The laser light L scans along the portion 10A where the part of the semiconductor layer 10 is removed, and a plurality of modified portions 200 are formed along the portion 10A where the part of the semiconductor layer 10 is removed. The modified portion 200 formed by the irradiation with the laser light L generates stress, and this stress causes cracks inside the wavelength conversion layer 30. The cracks extend in the thickness direction of the wavelength conversion layer 30 from the modified portion 200.

After the modified portion 200 is formed by the irradiation with the laser light L, as illustrated in FIG. 1K, a force is applied to the wavelength conversion layer 30 by using a pressing member 300, so that the wavelength conversion layer 30 is cleaved along the portion 10A where the part of the semiconductor layer 10 is removed. The pressing member 300 extends along the portion 10A where the part of the semiconductor layer 10 is removed. For example, a pressing force by the pressing member 300 is applied to the wavelength conversion layer 30 from the second surface 30a side. The wavelength conversion layer 30 that receives the pressing force from the second surface 30a side starts to crack from the third surface 30b side with, as a starting point, a crack that extends from the modified portion 200 and reaches the third surface 30b or reaches the vicinity of the third surface 30b. A groove 30c having a V-shaped cross section and opened in the third surface 30b is formed along the portion 10A where the part of the semiconductor layer 10 is removed and reaches the second surface 30a, so that the wavelength conversion layer 30 is cleaved. Alternatively, the pressing force by the pressing member 300 may be applied to the wavelength conversion layer 30 from the third surface 30b side.

When the layered body 101 is singulated into the plurality of light-emitting devices 1, a method of collectively cleaving, cutting, or etching the semiconductor layer 10 and the wavelength conversion layer 30 by the same method is conceivable. In the method of collectively cleaving the semiconductor layer 10 and the wavelength conversion layer 30, the semiconductor layer 10 is unlikely to be cleaved. In the method of collectively cutting the semiconductor layer 10 and the wavelength conversion layer 30 by using a blade, chipping is likely to occur in the semiconductor layer 10 harder than the wavelength conversion layer 30. In the method of collectively etching the semiconductor layer 10 and the wavelength conversion layer 30, it takes time to etch the wavelength conversion layer 30 thicker than the semiconductor layer 10, so that the manufacturing efficiency of the light-emitting device may be reduced.

According to the present embodiment, after the semiconductor layer 10 is separated into the plurality of semiconductor portions 60 above the wavelength conversion layer 30, the layered body 101 is singulated into the plurality of light-emitting devices 1 by cleaving the wavelength conversion layer 30; thus, respective methods suitable for the separation of the semiconductor layer 10 into the semiconductor portions 60 and the cleavage of the wavelength conversion layer 30 can be selected. Thus, the layered body 101 can be easily singulated into the plurality of light-emitting devices 1 while reducing damage to the layered body 101.

The third surface 30b of the wavelength conversion layer 30 in the light-emitting device 1 is a main light extraction surface. In the light-emitting device 1, light can also be extracted from the lateral surface of the semiconductor layer 10, the lateral surface of the light-transmissive layer 20, and the lateral surface of the wavelength conversion layer 30.

As illustrated in FIG. 1G, by also removing the part of the light-transmissive layer 20 in the step of separating the semiconductor layer 10 into the plurality of semiconductor portions 60, the singulation of the layered body 101 into the light-emitting devices 1 by cleaving the wavelength conversion layer 30 is facilitated. In the step of separating the semiconductor layer 10 into the plurality of semiconductor portions 60, a part of the wavelength conversion layer 30 located below the portion where the part of the semiconductor layer 10 and the part of the light-transmissive layer 20 are removed may also be removed to reduce the thickness of that part of the wavelength conversion layer 30. In this case, the cleavage of the wavelength conversion layer 30 is further facilitated.

A part of the second surface 30a of the wavelength conversion layer 30 located below the portion where the part of the semiconductor layer 10 and the part of the light-transmissive layer 20 are removed serves as an outer peripheral portion 30al exposed from the light-transmissive layer 20 and the semiconductor layer 10 in the light-emitting device 1 obtained by singulation, as illustrated in FIG. 1L.

In the step of providing the layered body 101 illustrated in FIG. 1F, the layered body 101 may further include a conductive layer 40, a first insulating film 51, and a second insulating film 52.

The conductive layer 40 is disposed above the p-side semiconductor layer 13 and is electrically connected to the p-side semiconductor layer 13. The conductive layer 40 has a function of diffusing, in a plane direction of the p-side semiconductor layer 13, electric current supplied from a p-side electrode to be described below.

The conductive layer 40 may have high reflectivity with respect to light emitted by the active layer 12. The conductive layer 40 having high reflectivity represents that the conductive layer 40 has a reflectance of 50% or more, preferably 60% or more with respect to the light emission peak wavelength of the light emitted by the active layer 12. For example, silver or aluminum can be used as a material for the conductive layer 40.

The first insulating film 51 covers an upper surface of the p-side semiconductor layer 13 and the conductive layer 40. The first insulating film 51 covers the conductive layer 40, so that the influence of moisture or the like above the conductive layer 40 can be reduced and the occurrence of migration of the conductive layer 40 can be reduced. For example, a silicon oxide film or a silicon nitride film can be used as the first insulating film 51.

The second insulating film 52 covers the first insulating film 51. The second insulating film 52 covers a part of the first n-side exposed surface 11a and a part of the second n-side exposed surface 11b. The second insulating film 52 further covers the lateral surface of the semiconductor layer 10 continuous with the first n-side exposed surface 11a and the upper surface of the p-side semiconductor layer 13, and the lateral surface of the semiconductor layer 10 continuous with the second n-side exposed surface 11b and the upper surface of the p-side semiconductor layer 13.

In the step of providing the layered body 101, the layered body 101 illustrated in FIG. 1F can be purchased to be provided. Alternatively, the step of providing the layered body 101 may include the following steps described with reference to FIGS. 1A to 1E.

The step of providing the layered body 101 may include a step of providing a wafer W, a step of removing a first substrate 91 of the wafer W to expose the first surface 10a of the semiconductor layer 10, a step of forming the light-transmissive layer 20 above the first surface 10a, and a step of bonding the wavelength conversion layer 30 to the light-transmissive layer 20.

In the step of providing the wafer W, as illustrated in FIG. 1A, the wafer W includes the first substrate 91 and the semiconductor layer 10 disposed above the first substrate 91. The wafer W may further include the conductive layer 40, the first insulating film 51, and the second insulating film 52 described above.

The first substrate 91 is a substrate used for formation of the semiconductor layer 10 by a metal organic chemical vapor deposition (MOCVD) method, for example. A sapphire substrate can be used as the first substrate 91, for example.

In the step of removing the first substrate 91 of the wafer W, the first substrate 91 can be removed by, for example, a laser lift-off method. The first substrate 91 is removed from the wafer W, so that the first surface 10a of the semiconductor layer 10 is exposed as illustrated in FIG. 1C.

On the exposed first surface 10a, the light-transmissive layer 20 is formed as illustrated in FIG. 1E. The light-transmissive layer 20 can be formed above the first surface 10a by a chemical vapor deposition (CVD) method, for example.

As illustrated in FIG. 1F, the wavelength conversion layer 30 is bonded to the light-transmissive layer 20, so that the layered body 101 is provided. The light-transmissive layer 20 and the wavelength conversion layer 30 can be directly bonded to each other in a state in which a pressing force and heat are applied.

The step of providing the layered body 101 preferably includes a step of bonding the wafer W to the second substrate 92 such that the second substrate is bonded to a surface side of the wafer W opposite to the first substrate 91, as illustrated in FIG. 1B. After the wafer W and the second substrate 92 are bonded to each other, the first substrate 91 is removed. Thus, even though the first substrate 91 is removed, the formation of the light-transmissive layer 20 and the bonding of the wavelength conversion layer 30 are easily performed in a state in which the semiconductor layer 10 is stably supported by the second substrate 92.

A substrate formed of the same material as the first substrate 91 can be used as the second substrate 92. The surface side of the wafer W opposite to the first substrate 91 is bonded to the second substrate 92 by a bonding member 93. For example, a resin can be used as a material for the bonding member 93.

The step of providing the layered body preferably further includes a step of, after the first surface 10a of the semiconductor layer 10 is exposed by removing the first substrate 91, roughening the first surface 10a as illustrated in FIG. 1D. This can improve the efficiency of light extraction from the first surface 10a.

For example, the first surface 10a can be roughened by wet etching using an alkaline solution such as tetramethylammonium hydroxide (TMAH) or dry etching using a chlorine-containing gas.

When the first surface 10a is roughened, the light-transmissive layer 20 is formed above the roughened first surface 10a as illustrated in FIG. 1E. In the direct bonding between the light-transmissive layer 20 and the wavelength conversion layer 30, flatness of a bonding surface is needed. When the light-transmissive layer 20 is formed above the roughened first surface 10a, the step of providing the layered body 101 preferably further includes a step of polishing, by chemical mechanical polishing (CMP), a surface of the light-transmissive layer 20 to which the wavelength conversion layer 30 is bonded. This can increase the flatness of the surface of the light-transmissive layer 20 to which the wavelength conversion layer 30 is bonded, thereby increasing the bonding strength between the light-transmissive layer 20 and the wavelength conversion layer 30. The surface of the light-transmissive layer 20 to which the wavelength conversion layer 30 is bonded preferably has a surface roughness (arithmetic average roughness) of 0.2 nm or less, for example.

After the wavelength conversion layer 30 is bonded to the light-transmissive layer 20, the second substrate 92 is removed. For example, the second substrate 92 can be detached from the bonding member 93 by irradiating an interface between the second substrate 92 and the bonding member 93 with laser light to evaporate the bonding member 93 located at the interface. Subsequently, the bonding member 93 can be removed from the semiconductor layer 10 by being dissolved using, for example, a chemical solution.

The thickness of the part of the semiconductor layer 10 removed in the step of separating the semiconductor layer 10 into the plurality of semiconductor portions 60 is preferably greater than the thickness of the light-transmissive layer 20. This can make it difficult for cracks to occur in the semiconductor layer 10 due to internal stress of the light-transmissive layer 20 formed above the first surface 10a of the semiconductor layer 10.

The method for manufacturing the light-emitting device according to the first embodiment can further include a step of forming a p-side electrode 71 and an n-side electrode 72 above the second insulating film 52 as illustrated in FIG. 1H.

The p-side electrode 71 is in contact with an upper surface of the conductive layer 40 in an opening formed in the second insulating film 52 and an opening formed in the first insulating film 51. The p-side electrode 71 is electrically connected to the p-side semiconductor layer 13 via the conductive layer 40. The n-side electrode 72 is in contact with the first n-side exposed surface 11a and is electrically connected to the n-side semiconductor layer 11.

Materials for the p-side electrode 71 and the n-side electrode 72, for example, a metal material such as Ag, Ni, Ti, Pt, Al, Ru, Rh, or Au, or an alloy thereof can be used. The p-side electrode 71 and the n-side electrode 72 may each be a single layer formed of any of the above metal materials, or may each have a layered structure including a plurality of metal layers.

The method for manufacturing the light-emitting device according to the first embodiment can further include a step of forming a p-side external connection electrode 81 and an n-side external connection electrode 82 as illustrated in FIG. 1I.

The p-side external connection electrode 81 is formed above the p-side electrode 71 and is electrically connected to the p-side electrode 71. The n-side external connection electrode 82 is formed above the n-side electrode 72 and is electrically connected to the n-side electrode 72. A thickness of the p-side external connection electrode 81 and a thickness of the n-side external connection electrode 82 are greater than a thickness of the p-side electrode 71 and a thickness of the n-side electrode 72.

As materials for the p-side external connection electrode 81 and the n-side external connection electrode 82, for example, a metal material such as Ag, Ni, Ti, Pt, Al, Ru, Rh, or Au, or an alloy thereof can be used. Each of the p-side external connection electrode 81 and the n-side external connection electrode 82 may be a single layer formed of any of the above metal materials, or may have a layered structure including a plurality of metal layers.

Steps of forming the p-side electrode 71, the n-side electrode 72, the p-side external connection electrode 81, and the n-side external connection electrode 82 may each be performed at discretionary timing as long as the step is performed before the wavelength conversion layer 30 is cleaved. When a resist mask is used in the step of removing the part of the semiconductor layer 10 by etching, the resist mask is preferably disposed above the layered body 101 before the p-side external connection electrode 81 and the n-side external connection electrode 82 are formed. In that case, the resist mask can be disposed above the layered body 101 in a state of being thinner than the layered body 101 in a state in which the p-side external connection electrode 81 and the n-side external connection electrode 82 are formed, and the accuracy of patterning of the resist mask by exposure and development can be easily improved.

### Second Embodiment

A method for manufacturing a light-emitting device 2 according to a second embodiment is described with reference to FIGS. 2A and 2B.

According to the second embodiment, as illustrated in FIG. 2A, in the step of separating the semiconductor layer 10 into the plurality of semiconductor portions 60, the light-transmissive layer 20 is exposed from the semiconductor layer 10 at the portion 10A where the part of the semiconductor layer 10 is removed. At least a portion of the light-transmissive layer 20 remains above the second surface 30a of the wavelength conversion layer 30 below the portion 10A where the part of the semiconductor layer 10 is removed. Accordingly, the light-transmissive layer 20 can protect the wavelength conversion layer 30 from etching, and helps prevent deterioration of the wavelength conversion layer 30. In the second embodiment shown in FIGS. 2A and 2B, a portion of the light-transmissive layer 20 in the thickness direction is removed and a portion of the light-transmissive layer 20 in the thickness direction remains above the second surface 30a of the wavelength conversion layer 30 below the portion 10A where the part of the semiconductor layer 10 is removed. Alternatively, it is possible to not remove any of the thickness of the light-transmissive layer 20 so that all of the thickness of the light-transmissive layer 20 remains above the second surface 30a of the wavelength conversion layer 30 below the portion 10A where the part of the semiconductor layer 10 is removed.

Subsequently, in the step of singulating the layered body 101 into a plurality of light-emitting devices 2, the light-transmissive layer 20 and the wavelength conversion layer 30 are cleaved along the portion 10A where the part of the semiconductor layer 10 is removed. The light-transmissive layer 20 is also cleaved along with the cleavage of the wavelength conversion layer 30 described above.

According to the second embodiment, as illustrated in FIG. 2B, in the light-emitting device 2 obtained by singulation, the light-transmissive layer 20 is disposed above the outer peripheral portion 30al of the second surface 30a of the wavelength conversion layer 30. Thus, light from the semiconductor layer 10 can be guided to the entire wavelength conversion layer 30, thereby achieving the light-emitting device 2 in which the luminance unevenness of light emitted from the wavelength conversion layer 30 is reduced.

### Third Embodiment

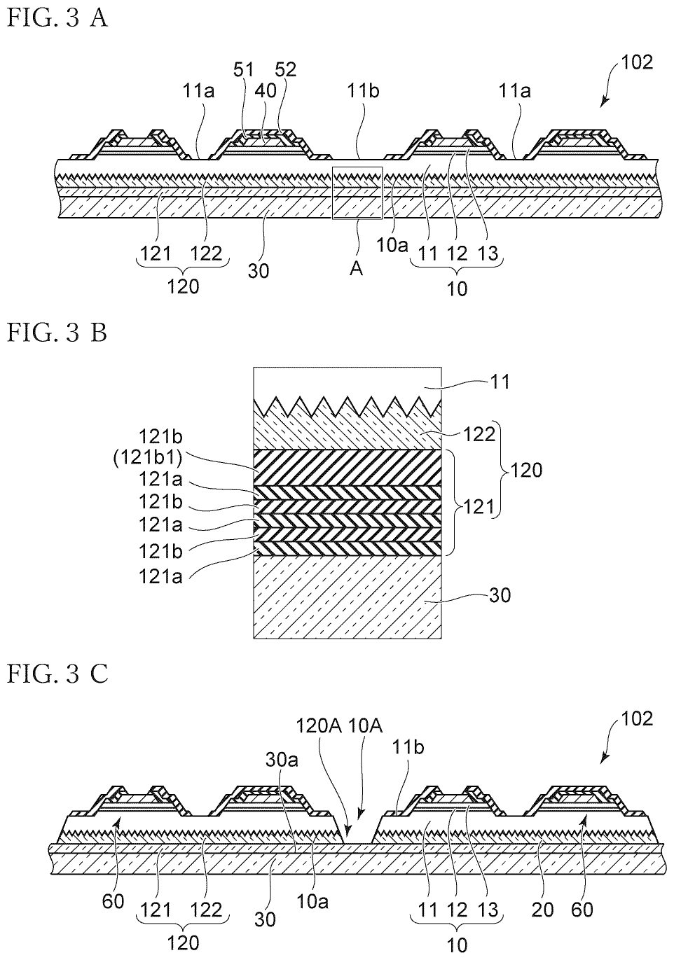

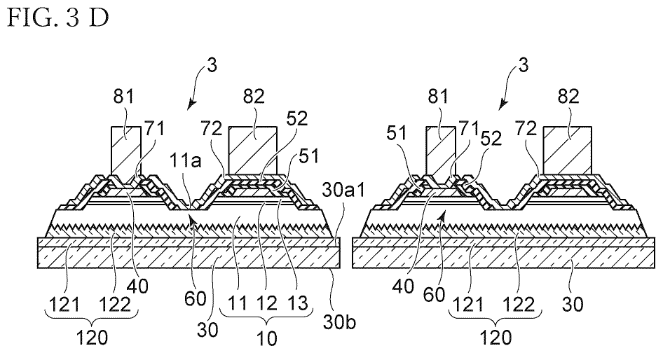

A method for manufacturing a light-emitting device 3 according to a third embodiment is described with reference to FIGS. 3A to 3D.

According to the third embodiment, as illustrated in FIG. 3A, in a step of providing a layered body 102, a light-transmissive layer 120 includes a first light-transmissive layer 121 disposed above the wavelength conversion layer 30 and a second light-transmissive layer 122 disposed above the first light-transmissive layer 121. The second light-transmissive layer 122 is located between the first light-transmissive layer 121 and the semiconductor layer 10. As a material for the second light-transmissive layer 122, the same material as the material for the light-transmissive layer 20 in the first and second embodiments can be used.

As illustrated in FIG. 3B being an enlarged cross-sectional view of a portion A in FIG. 3A, the first light-transmissive layer 121 includes a plurality of dielectric layers. The plurality of dielectric layers include first dielectric layers 121a and second dielectric layers 121b alternately layered between the wavelength conversion layer 30 and the second light-transmissive layer 122. The number of layered pairs of the first dielectric layer 121a and the second dielectric layer 121b is not limited to the number of pairs illustrated in FIG. 3B.

The first light-transmissive layer 121 including the plurality of dielectric layers has characteristics of easily transmitting light in a wavelength region of light emitted by the active layer 12 and easily reflecting light in a wavelength region of light wavelength-converted by the wavelength conversion layer 30. The first light-transmissive layer 121 having such characteristics can improve efficiency of light extraction from the third surface 30b of the wavelength conversion layer 30 in the light-emitting device 3.

For example, niobium oxide (Nb₂O₅) can be used as a material for one of the first dielectric layer 121a and the second dielectric layer 121b, and silicon oxide (SiO₂) can be used as a material for the other dielectric layer.

According to the third embodiment, as illustrated in FIG. 3C, in the step of separating the semiconductor layer 10 into the plurality of semiconductor portions 60, the first light-transmissive layer 121 is exposed from the semiconductor layer 10 and the second light-transmissive layer 122 at the portion 10A where the part of the semiconductor layer 10 is removed. The first light-transmissive layer 121 remains above the second surface 30a of the wavelength conversion layer 30 below the portion 10A where the part of the semiconductor layer 10 is removed. Accordingly, the first light-transmissive layer 121 can protect the wavelength conversion layer 30 from etching, and helps prevent deterioration of the wavelength conversion layer 30.

Subsequently, in the step of singulating the layered body 102 into a plurality of light-emitting devices 3, the first light-transmissive layer 121 and the wavelength conversion layer 30 are cleaved along the portion 10A where the part of the semiconductor layer 10 is removed. The first light-transmissive layer 121 is also cleaved along with the cleavage of the wavelength conversion layer 30 described above.

According to the third embodiment, as illustrated in FIG. 3D, in the light-emitting device 3 obtained by singulation, the first light-transmissive layer 121 is disposed above the outer peripheral portion 30al of the second surface 30a of the wavelength conversion layer 30.

In the step of providing the layered body 102 of the third embodiment, as illustrated in FIG. 3B, a dielectric layer (second dielectric layer 121b1) in contact with the second light-transmissive layer 122 among the plurality of dielectric layers of the first light-transmissive layer 121 is preferably thicker than each of the dielectric layers other than the dielectric layer (second dielectric layer 121b1) in contact with the second light-transmissive layer 122 among the plurality of dielectric layers. Thus, in the etching in the step of separating the semiconductor layer 10 into the plurality of semiconductor portions 60, a predetermined number of pairs of the first dielectric layer 121a and the second dielectric layer 121b can be easily left above the second surface 30a of the wavelength conversion layer 30 below the portion 10A where the part of the semiconductor layer 10 is removed. In other words, in the light-emitting device 3 obtained by singulation, the predetermined number of pairs of the first dielectric layer 121a and the second dielectric layer 121b can be easily left above the outer peripheral portion 30al of the second surface 30a of the wavelength conversion layer 30. Thus, light wavelength-converted by the wavelength conversion layer 30 and traveling toward the outer peripheral portion 30al is reflected by the first light-transmissive layer 121, so that the efficiency of light extraction from the third surface 30b can be improved.

The embodiments according to the present disclosure can include the methods for manufacturing the light emitting device as below.

The embodiments of the present invention have been described above with reference to specific examples. However, the present invention is not limited to these specific examples. All aspects that can be practiced by a person skilled in the art changing the design as appropriate based on the above-described embodiments of the present invention are also included in the scope of the present invention, as long as they encompass the spirit of the present invention. In addition, in the spirit of the present invention, a person skilled in the art can conceive of various alteration examples and modifications, and those alteration examples and modifications will also fall within the scope of the present invention.

1. A method for manufacturing a light-emitting device, the method comprising:
providing a layered body including a wavelength conversion layer, a light-transmissive layer disposed above the wavelength conversion layer, and a semiconductor layer disposed above the light-transmissive layer;
separating the semiconductor layer into a plurality of semiconductor portions above the wavelength conversion layer by removing a part of the semiconductor layer; and
singulating the layered body into a plurality of light-emitting devices by cleaving the wavelength conversion layer along a portion where the part of the semiconductor layer is removed.

2. The method for manufacturing a light-emitting device, according to claim 1, wherein in the separating of the semiconductor layer into the plurality of semiconductor portions, the part of the semiconductor layer is removed by etching.

3. The method for manufacturing a light-emitting device, according to claim 2, wherein in the separating of the semiconductor layer into the plurality of semiconductor portions, a part of the light-transmissive layer is also removed, and the wavelength conversion layer is exposed from the semiconductor layer and the light-transmissive layer in the portion where the part of the semiconductor layer is removed.

4. The method for manufacturing a light-emitting device, according to claim 1, wherein in the separating of the semiconductor layer into the plurality of semiconductor portions, a part of the light-transmissive layer is also removed, and the wavelength conversion layer is exposed from the semiconductor layer and the light-transmissive layer in the portion where the part of the semiconductor layer is removed.

5. The method for manufacturing a light-emitting device, according to claim 1, wherein
in the separating of the semiconductor layer into the plurality of semiconductor portions, the light-transmissive layer is exposed from the semiconductor layer at the portion where the part of the semiconductor layer is removed, and
in the singulating of the layered body into the plurality of light-emitting devices, the light-transmissive layer and the wavelength conversion layer are cleaved along the portion where the part of the semiconductor layer is removed.

6. The method for manufacturing a light-emitting device, according to claim 2, wherein
in the separating of the semiconductor layer into the plurality of semiconductor portions, the light-transmissive layer is exposed from the semiconductor layer at the portion where the part of the semiconductor layer is removed, and
in the singulating of the layered body into the plurality of light-emitting devices, the light-transmissive layer and the wavelength conversion layer are cleaved along the portion where the part of the semiconductor layer is removed.

7. The method for manufacturing a light-emitting device, according to claim 1, wherein
in the providing of the layered body, the light-transmissive layer is disposed above the wavelength conversion layer, the light-transmissive layer includes a first light-transmissive layer and a second light-transmissive layer disposed above the first light-transmissive layer, and the first light-transmissive layer includes a plurality of dielectric layers
in the separating of the semiconductor layer into the plurality of semiconductor portions, the first light-transmissive layer is exposed from the semiconductor layer and the second light-transmissive layer at the portion where the part of the semiconductor layer is removed, and
in the singulating of the layered body into the plurality of light-emitting devices, the first light-transmissive layer and the wavelength conversion layer are cleaved along the portion where the part of the semiconductor layer is removed.

8. The method for manufacturing a light-emitting device, according to claim 7, wherein in the providing of the layered body, a dielectric layer in contact with the second light-transmissive layer among the plurality of dielectric layers is thicker than each of the dielectric layers other than the dielectric layer in contact with the second light-transmissive layer among the plurality of dielectric layers.

9. The method for manufacturing a light-emitting device, according to claim 2, wherein
in the providing of the layered body, the light-transmissive layer is disposed above the wavelength conversion layer, the light-transmissive layer includes a first light-transmissive layer and a second light-transmissive layer disposed above the first light-transmissive layer, and the first light-transmissive layer includes a plurality of dielectric layers
in the separating of the semiconductor layer into the plurality of semiconductor portions, the first light-transmissive layer is exposed from the semiconductor layer and the second light-transmissive layer at the portion where the part of the semiconductor layer is removed, and
in the singulating of the layered body into the plurality of light-emitting devices, the first light-transmissive layer and the wavelength conversion layer are cleaved along the portion where the part of the semiconductor layer is removed.

10. The method for manufacturing a light-emitting device, according to claim 9, wherein in the providing of the layered body, a dielectric layer in contact with the second light-transmissive layer among the plurality of dielectric layers is thicker than each of the dielectric layers other than the dielectric layer in contact with the second light-transmissive layer among the plurality of dielectric layers.

11. The method for manufacturing a light-emitting device, according to claim 1, wherein a thickness of the part of the semiconductor layer removed in the separating of the semiconductor layer into the plurality of semiconductor portions is greater than a thickness of the light-transmissive layer.

12. The method for manufacturing a light-emitting device, according to claim 2, wherein a thickness of the part of the semiconductor layer removed in the separating of the semiconductor layer into the plurality of semiconductor portions is greater than a thickness of the light-transmissive layer.

13. The method for manufacturing a light-emitting device, according to claim 1, wherein the providing of the layered body includes
providing a wafer including a first substrate and the semiconductor layer disposed above the first substrate;
exposing a first surface of the semiconductor layer by removing the first substrate of the wafer;
forming the light-transmissive layer above the first surface; and
bonding the wavelength conversion layer to the light-transmissive layer.

14. The method for manufacturing a light-emitting device, according to claim 13, wherein
the providing of the layered body further includes bonding the wafer to a second substrate such that the second substrate is bonded to a surface side of the wafer opposite to the first substrate, and
after the wafer and the second substrate are bonded to each other, the first substrate is removed.

15. The method for manufacturing a light-emitting device, according to claim 13, wherein the providing of the layered body further includes roughening the first surface of the semiconductor layer.

16. The method for manufacturing a light-emitting device, according to claim 15, wherein
in the forming of the light-transmissive layer, the light-transmissive layer is formed above the first surface having been roughened, and
the providing of the layered body further includes polishing, by chemical mechanical polishing, a surface of the light-transmissive layer to which the wavelength conversion layer is bonded.

17. The method for manufacturing a light-emitting device, according to claim 2, wherein the providing of the layered body includes
providing a wafer including a first substrate and the semiconductor layer disposed above the first substrate;
exposing a first surface of the semiconductor layer by removing the first substrate of the wafer;
forming the light-transmissive layer above the first surface; and
bonding the wavelength conversion layer to the light-transmissive layer.

18. The method for manufacturing a light-emitting device, according to claim 17, wherein
the providing of the layered body further includes bonding the wafer to a second substrate such that the second substrate is bonded to a surface side of the wafer opposite to the first substrate, and
after the wafer and the second substrate are bonded to each other, the first substrate is removed.

19. The method for manufacturing a light-emitting device, according to claim 17, wherein the providing of the layered body further includes roughening the first surface of the semiconductor layer.

20. The method for manufacturing a light-emitting device, according to claim 19, wherein
in the forming of the light-transmissive layer, the light-transmissive layer is formed above the first surface having been roughened, and
the providing of the layered body further includes polishing, by chemical mechanical polishing, a surface of the light-transmissive layer to which the wavelength conversion layer is bonded.
